(19) United States
(12) Patent Application Publication
(10) Pub. No.: US 2014/0175426 A1
(43) Pub. Date: Jun. 26, 2014

(54) THIN FILM TRANSISTOR

(71) Applicant: HON HAI PRECISION INDUSTRY CO., LTD., New Taipei (TW)

(72) Inventor: JIAN-SHIHN TSANG, Tu-Cheng (TW)

(73) Assignee: HON HAI PRECISION INDUSTRY CO., LTD., New Taipei (TW)

(21) Appl. No.: 14/014,406

(22) Filed: Aug. 30, 2013

(30) Foreign Application Priority Data
Dec. 25, 2012 (TW) 101149892

(51) Int. Cl. H01L 29/786

(52) U.S. Cl. CPC H01L 29/7869
USPC 257/43

(57) ABSTRACT

A thin film transistor includes a substrate, a gate electrode formed on the substrate and a gate insulating layer formed on the substrate and covering the gate electrode. A first ion capturing layer is formed on the gate insulating layer. A channel layer is formed on the ion capturing layer. And, a source electrode and a drain electrode are electrically connected with the channel layer.

### BACKGROUND

1. Technical Field

The disclosure generally relates to a thin film transistor.

2. Description of Related Art

Nowadays, thin film transistors have been widely used in display devices to make the display devices become thinner and smaller. A typical thin film transistor includes a channel layer, a gate electrode, a source electrode and a drain electrode formed on the channel layer. The thin film transistor is turned on or turned off by controlling a voltage applied to the gate electrode.

A channel layer of a thin film transistor is generally made of transparent oxide semiconductor, such as indium gallium zinc oxide (InGaZnO), indium tin zinc oxide (InSnZnO), and indium zinc oxide (InZnO). Major carriers in the channel layer are formed by doping or lattice defects, such as oxygen vacancies, metal vacancies, interstitials, or oxygen associated defects. Therefore, a concentration of the major carriers is easy to be affected by oxygen content, steam, illumination and plasma damage in outer environment.

What is needed, therefore, is a thin film transistor to overcome the above described disadvantages.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a cross sectional view of a thin film transistor in accordance with a first embodiment of the present disclosure.

FIG. 2 is a cross sectional view of a thin film transistor in accordance with a second embodiment of the present disclosure.

FIG. 3 is a cross sectional view of a thin film transistor in accordance with a third embodiment of the present disclosure.

### DETAILED DESCRIPTION

Embodiments of thin film transistors will now be described in detail below and with reference to the drawings.

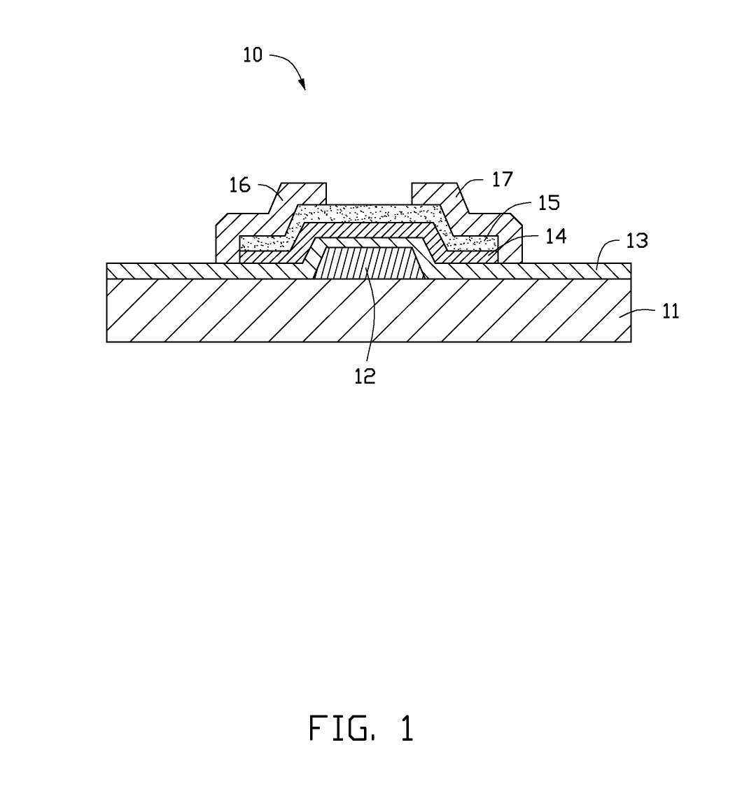

Referring to FIG. 1, a thin film transistor 10 in accordance with a first embodiment includes a substrate 11, a gate electrode 12, a gate insulating layer 13, an ion capturing layer 14, a channel layer 15, a source electrode 16 and a drain electrode 17.

The substrate 11 is configured to support the gate electrode 12. The substrate 11 is made of a material selected from glass, quartz, silicon, polycarbonate, polymethyl methacrylate or metallic foil.

The gate electrode 12 is formed on an upper surface of the substrate 11. In this embodiment, the gate electrode 12 is located in a central portion of the substrate 11. The gate electrode 12 is made of a material selected from Cu, Al, Ni, Mg, Cr, Mo, W or alloys thereof.

The gate insulating layer 13 covers on the gate electrode 12. In this embodiment, the gate electrode 12 extends to contact the substrate 11. The gate insulating layer 13 is made of a material selected from SiOx, SiNx and SiONx, or insulating materials with a high dielectric constant such as Ta₂O₅ and HfO₂.

The ion capturing layer 14 is formed on an upper surface of the gate insulating layer 13. In this embodiment, the ion capturing layer 14 is located in a central portion of the gate insulating layer 13. A main ingredient of the ion capturing layer 14 includes at least one of C, Si, Ge, Sn, Pb, Mg, Ca, Sr, Ba, Ti, Ni, Al, Co, Pt, Pd and Mn. A doping ingredient of the ion capturing layer 14 includes at least one of Si, Ge, C, N, Al, B, Mg, Ca, Sr, Ba, Ti, Ni and Co.

The ion capturing layer 14 can be a planar structure or a three-dimensional structure. When the ion capturing layer 14 is a planar structure, the ion capturing layer 14 can be a grapheme layer or a Si atomic doping layer. The doping ingredient of the ion capturing layer 14 is selected from one of Ge, C, N, Al, B, Mg, Ca, Sr, Ba, Ti, Ni and Co. When the ion capturing layer 14 is a three-dimensional structure, the ion capturing layer 14 can be made by a plurality of grapheme layers stacked on each other. In alternative embodiments, the ion capturing layer 14 can also be a porous semiconductor layer, or a non-crystal semiconductor layer, and a material of the ion capturing layer 14 can be selected from Si, Ge, SiGe, or C. For example, the ion capturing layer 14 can be a porous SiₓGe₁₋ₓ (0≦x≦1) semiconductor layer; or the ion capturing layer 14 can be a non-crystal SiₓGe₁₋ₓ(0≦x≦1) semiconductor layer. The ion capturing layer 14 can also be a metal layer, which is selected from one of Al, Sn, Pb, Mg, Ca, Sr, Ba, Ti, Ni, Co, Pt, Pd, Mn and alloys thereof. In that time, the ion capturing layer 14 is not electrically connected with the source electrode 16 and the drain electrode 17 at the same time.

The channel layer 15 is formed on an upper surface of the ion capturing layer 14 and covers the ion capturing layer 14. The channel layer 15 can be a non-crystal structure, a poly-crystal structure, a mono-crystal structure or a mini-crystal structure. The channel layer 15 is made of oxide semiconductor materials. Preferably, the channel layer 15 is a metal oxide semiconductor layer, and the metal ion in the channel layer 15 is selected from at least one of In, Ga, Zn, Sn, Al, Pb, Mo, Mn, Mg, Ge and Pd. In this embodiment, the channel layer 15 is an InGaZnO layer.

The source electrode 16 and the drain electrode 17 are formed two opposite ends of an upper surface of the channel layer 15. The source electrode 16 extends along a direction away from the drain electrode 17 and covers lateral sides of the channel layer 15 and ion capturing layer 14. The drain electrode 17 extends along a direction away from the source electrode 16 and covers lateral sides of the channel layer 15 and ion capturing layer 14. In this embodiment, the source electrode 16 and the drain electrode 17 extends to contact the upper surface of the gate insulating layer 13. When, the channel layer 15 totally covers the ion capturing layer 14, or the ion capturing layer 14 is not electrically connected with the source electrode 16 and the drain electrode 17 at the same time, the ion capturing layer 14 can be a metal layer, which is made of a material selected from one of Al, Sn, Pb, Mg, Ca, Sr, Ba, Ti, Ni, Co, Pt, Pd, Mn and alloys thereof.

In the thin film transistor 10 described above, the ion capturing layer 14 can capture the oxygen ions in oxygen gas or steam, thereby preventing oxygen ions in outer environment from permeating into the channel layer 15. Also, the ion capturing layer 14 can prevent the oxygen ions in the channel layer 15 from diffusing into the outer environment and reduces a variation of the lattice defects in relationship with oxygen content. Therefore, the thin film transistor 10 is not easy to be affected by oxygen content or steam in outer environment.

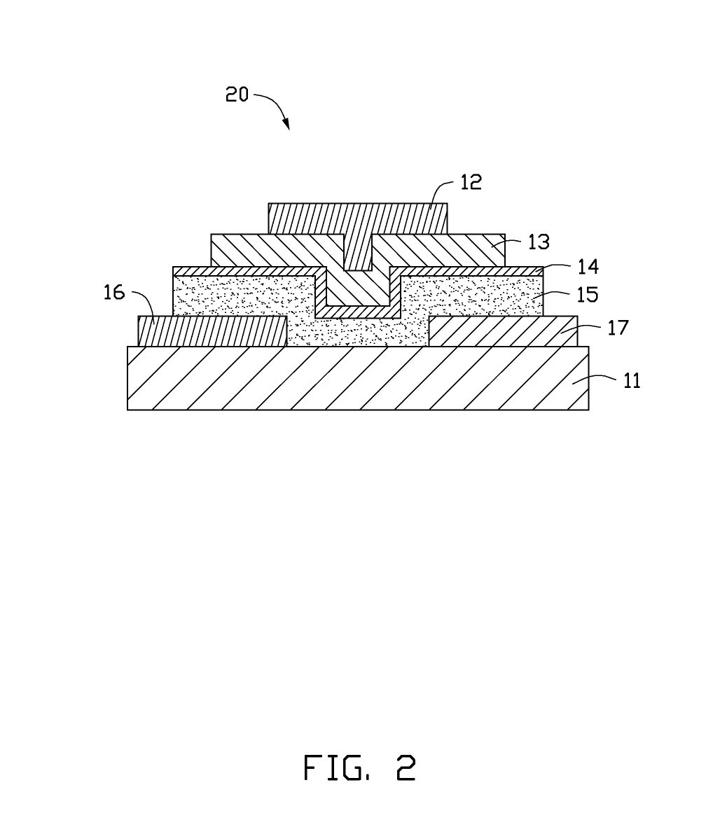

Referring to FIG. 2, a thin film transistor 20 in accordance with a second embodiment includes a substrate 11, a gate electrode 12, a gate insulating layer 13, an ion capturing layer 14, a channel layer 15, a source electrode 16 and a drain electrode 17.

The source electrode 16 and the drain electrode 17 are located at two opposite ends of the upper surface of the substrate 11. The channel layer 15 is located in a middle portion of the upper surface of the substrate 11 and partly covers the source electrode 16 and the drain electrode 17. The ion capturing layer 14 is formed on the upper surface of the channel layer 15 and covers the channel layer 15. The gate insulating layer 13 is located in a middle portion of the upper surface of the ion capturing layer 14. The gate electrode 12 is formed on the gate insulating layer 13 and located in a middle portion of the upper surface of the gate insulating layer 13.

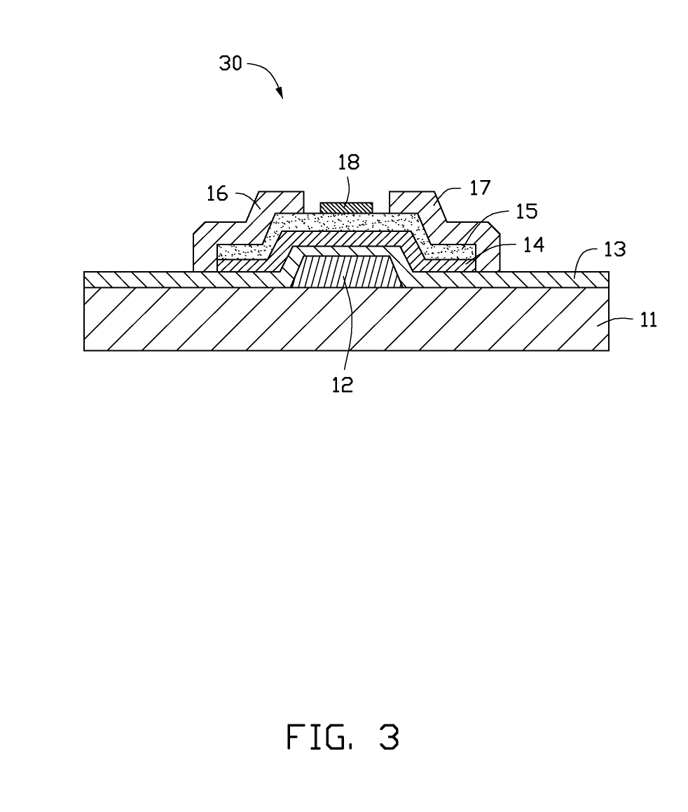

Referring to FIG. 3, a thin film transistor 30 in accordance with a third embodiment includes a substrate 11, a gate electrode 12, a gate insulating layer 13, an ion capturing layer 14, a channel layer 15, a source electrode 16 and a drain electrode 17. Different from the first embodiment, the thin film transistor 30 further includes a second ion capturing layer 18. The second ion capturing layer 18 is located at one side of the channel layer 15 away from the gate insulating layer 13. In this embodiment, the second ion capturing layer 18 is located between the source electrode 16 and the drain electrode 17, and is not electrically connected with the source electrode 16 and the drain electrode 17. In alternative embodiments, the second ion capturing layer 18 can be electrically connected with one of the source electrode 16 and the drain electrode 17.

Preferably, the thin film transistor is not limited to the top gate structure or bottom gate structure described above. It also can be thin film transistor with coplanar structure or non-coplanar structure, staggered thin film transistor, or inverted staggered thin film transistor.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A thin film transistor, comprising:
a substrate;
a gate electrode formed on the substrate;
a gate insulating layer formed on the substrate and covering the gate electrode;
a first ion capturing layer formed on the gate insulating layer;
a channel layer formed on the ion capturing layer; and
a source electrode and a drain electrode electrically connected with the channel layer.

2. The thin film transistor of claim 1, wherein the channel layer is an oxide semiconductor layer.

3. The thin film transistor of claim 2, wherein the channel layer is a metal oxide semiconductor layer, the metal oxide semiconductor layer comprising metal ions selected from at least one of In, Ga, Zn, Sn, Al, Pb, Mo, Mn, Mg, Ge and Cd.

4. The thin film transistor of claim 3, wherein the channel layer is made of InGaZnO.

5. The thin film transistor of claim 1, wherein the first ion capturing layer comprises an ingredient selected from at least one of C, Si, Ge, Sn, Pb, Mg, Ca, Sr, Ba, Ti, Ni, Al, Co, Pt, Pd and Mn.

6. The thin film transistor of claim 1, wherein the first ion capturing layer comprises a plurality of grapheme layers stacked on each other.

7. The thin film transistor of claim 1, wherein the first ion capturing layer is a Si atomic doping layer.

8. The thin film transistor of claim 1, wherein the first ion capturing layer is doped with one of Si, Ge, C, N, Al, B, Mg, Ca, Sr, Ba, Ti, Ni and Co.

9. The thin film transistor of claim 1, wherein the first ion capturing layer is a metal layer and does not electrically connected with the source electrode and the drain electrode at the same time.

10. The thin film transistor of claim 9, wherein the first ion capturing layer is made of a material selected from Al, Sn, Pb, Mg, Ca, Sr, Ba, Ti, Ni, Co, Pt, Pd, Mn and alloys thereof.

11. The thin film transistor of claim 1, further comprising a second ion capturing layer formed on a surface of the channel layer away from the first ion capturing layer, the second ion capturing layer located between the source electrode and the drain electrode.

12. A thin film transistor, comprising:
a substrate;
a source electrode and a drain electrode located at two opposite ends of an upper surface of the substrate;
a channel layer located in a middle portion of the upper surface of the substrate and partly covering the source electrode and the drain electrode;
an ion capturing layer formed on an upper surface of the channel layer;
a gate insulating layer formed on an upper surface of the ion capturing layer; and
a gate electrode formed on an upper surface of the gate insulating layer.

13. The thin film transistor of claim 12, wherein the channel layer is an oxide semiconductor layer.

14. The thin film transistor of claim 13, wherein the channel layer is a metal oxide semiconductor layer, the metal oxide semiconductor layer comprising metal ions selected from at least one of In, Ga, Zn, Sn, Al, Pb, Mo, Mn, Mg, Ge and Cd.

15. The thin film transistor of claim 14, wherein the channel layer is made of InGaZnO.

16. The thin film transistor of claim 12, wherein the ion capturing layer comprises an ingredient selected from at least one of C, Si, Ge, Sn, Pb, Mg, Ca, Sr, Ba, Ti, Ni, Al, Co, Pt, Pd and Mn.

17. The thin film transistor of claim 12, wherein the first ion capturing layer comprises a plurality of grapheme layers stacked on each other.

18. The thin film transistor of claim 12, wherein the ion capturing layer is doped with one of Si, Ge, C, N, Al, B, Mg, Ca, Sr, Ba, Ti, Ni and Co.

19. The thin film transistor of claim 12, wherein the ion capturing layer is a metal layer and does not electrically connected with the source electrode and the drain electrode at the same time.

20. The thin film transistor of claim 19, wherein the ion capturing layer is made of a material selected from Al, Sn, Pb, Mg, Ca, Sr, Ba, Ti, Ni, Co, Pt, Pd, Mn and alloys thereof.
